(19) United States
(12) Patent Application Publication
(10) Pub. No.: US 2012/0319745 A1
(43) Pub. Date: Dec. 20, 2012

(54) FREQUENCY MULTIPLIER OSCILLATION CIRCUIT AND METHOD OF MULTIPLYING FUNDAMENTAL WAVE

(76) Inventor: Masaharu Ito, Tokyo (JP)

(21) Appl. No.: 13/578,376

(22) PCT Filed: Dec. 6, 2010
(86) PCT No.: PCT/JP2010/007076

§ 371 Date: Aug. 10, 2012

(30) Foreign Application Priority Data
Feb. 23, 2010 (JP) 2010-037203

(51) Int. Cl. H03B 19/00

(52) U.S. Cl. 327/119

(57) ABSTRACT

A frequency multiplier oscillation circuit (and a method of multiplying a fundamental wave) includes an oscillation unit, a multiplication unit, and a fundamental wave component removal unit. The oscillation unit outputs a fundamental wave. The multiplication unit multiplies the fundamental wave to output the multiplied wave. The fundamental wave component removal unit cancels a fundamental wave component included in the multiplied wave based on the fundamental wave that is output from the oscillation unit to output the multiplied wave to an output terminal.

### TECHNICAL FIELD

The present invention relates to a frequency multiplier oscillation circuit and a method of multiplying a fundamental wave, and more specifically, to a frequency multiplier oscillation circuit and a method of multiplying a fundamental wave which can sufficiently suppressing spurious waves.

### BACKGROUND ART

In general, there is a limitation in gain of high-frequency waves obtained by active elements. Therefore, in a signal source that generates high-frequency signals, such a configuration is often employed that executes oscillation at a frequency lower than a desired frequency, converts the low frequency to harmonics, and then outputs the harmonics. Further, a configuration in which a multiplier is connected to outside is often employed. However, according to these configurations, there is a problem that spurious fundamental and unwanted harmonics are output in addition to a desired harmonic.

Patent literature 1 discloses an oscillator that converts a low-frequency signal to harmonics to output the harmonics. This oscillator is a differential oscillator having a push-push configuration that outputs even harmonics from a virtual ground unit of differential signals. According to this configuration, an output terminal is provided in the virtual ground unit for fundamental and odd harmonics, thereby suppressing leakage of the output of spurious fundamental wave and odd harmonics.

Further, a configuration that receives a single-phase signal is typically used as an oscillator that connects a multiplier to outside. In this configuration, multistage filters are required in order to sufficiently suppress leakage of spurious waves other than a desired harmonic in a broad band. This leads to an increase in size of the oscillator. Further, when an operating frequency band of the oscillator is wide (multiplication number<band upper limit/band lower limit), the spurious waves that should be suppressed enter the frequency band of the desired harmonic. Accordingly, the spurious waves cannot he suppressed effectively by a filter.

Non patent literature 1 discloses a multiplier which requires no filter to suppress spurious waves. This multiplier is a balanced multiplier that receives differential signals by two non-linear elements to synthesize output signals from the non-linear elements. According to this configuration, the fundamental wave of the input signal and the odd harmonics have opposite phases with each other in a synthetic point of the two non-linear elements. Thus, leakage of the spurious waves to an output terminal is suppressed.

### CITATION LIST

### Patent Literature

PTL 1: Japanese Unexamined Patent Application Publication No. 2007-150753

### Non Patent Literature

NPL 1: Juo-Jung Hung, et al. “A high-Efficiency Miniaturized SiGe Ku-Band Balanced Frequency Doubler”, 2004 Radio Frequency Integrated Circuits Digest, pp. 219-222

### SUMMARY OF INVENTION

### Technical Problem

However, the oscillator disclosed in Patent literature 1 aims to operate to obtain large harmonics generated inside the oscillator. The problem here is an increase in phase noise due to high non-linearity.

Further, two non-linear elements are required in the balanced multiplier disclosed in Non-patent literature 1. Thus, the problem is an increase in the size of the oscillator.

The present invention has been made based on the aforementioned background, and one exemplary object of the present invention is to provide a frequency multiplier oscillation circuit which can he made compact and effectively suppress spurious waves. and a method of multiplying a fundamental wave.

### Solution to Problem

A frequency multiplier oscillation circuit according to one exemplary aspect of the present invention includes: an oscillation unit for outputting a fundamental wave; a multiplication unit for multiplying the fundamental wave output from the oscillation unit to output the multiplied wave; and a fundamental wave component removal unit for cancelling a fundamental wave component included in the multiplied wave based on the fundamental wave output from the oscillation unit to output the multiplied wave.

A method of multiplying a fundamental wave according to another exemplary aspect of the present invention includes: outputting a fundamental wave from an oscillation unit; multiplying the fundamental wave to output the multiplied wave; and cancelling a fundamental wave component included in the multiplied wave based on the fundamental wave output from the oscillation unit to output the multiplied wave.

### Advantageous Effects of Invention

According to the present invention, it is possible to provide a frequency multiplier oscillation circuit which can be made compact and effectively suppress spurious waves, and a method of multiplying a fundamental wave.

### BRIEF DESCRIPTION OF DRAWINGS

FIG. 1 A configuration diagram of a frequency multiplier oscillation circuit 100 according to a first exemplary embodiment.

FIG. 2 A configuration diagram of a frequency multiplier oscillation circuit 200 according to a second exemplary embodiment.

FIG. 3A A configuration diagram showing a configuration example of a coupling element 7 in the frequency multiplier oscillation circuit 200.

FIG. 3B A configuration diagram showing a configuration example of the coupling element 7 in the frequency multiplier oscillation circuit 200.

FIG. 3C A configuration diagram showing a configuration example of the coupling element 7 in the frequency multiplier oscillation circuit 200.

FIG. 4 A configuration diagram showing a configuration of a frequency multiplier oscillation circuit 201, which is obtained by modifying the configuration of the frequency multiplier oscillation circuit 200.

FIG. 5 A configuration diagram of a frequency multiplier oscillation circuit 300 according to a third exemplary embodiment.

FIG. 6 A configuration diagram of a frequency multiplier oscillation circuit 400 according to a fourth exemplary embodiment.

FIG. 7A A graph showing frequency characteristics of output power of multiplied waves when the frequency multiplier oscillation circuit 400 outputs second harmonics.

FIG. 7B A graph showing frequency characteristics of a fundamental wave suppression level when the frequency multiplier oscillation circuit 400 outputs the second harmonics.

FIG. 8A A graph showing frequency characteristics of output power of multiplied waves when the frequency multiplier oscillation circuit 400 outputs third harmonics.

FIG. 8B A graph showing frequency characteristics of a fundamental wave suppression level when the frequency multiplier oscillation circuit 400 outputs the third harmonics.

### DESCRIPTION OF EMBODIMENTS

### First Exemplary Embodiment

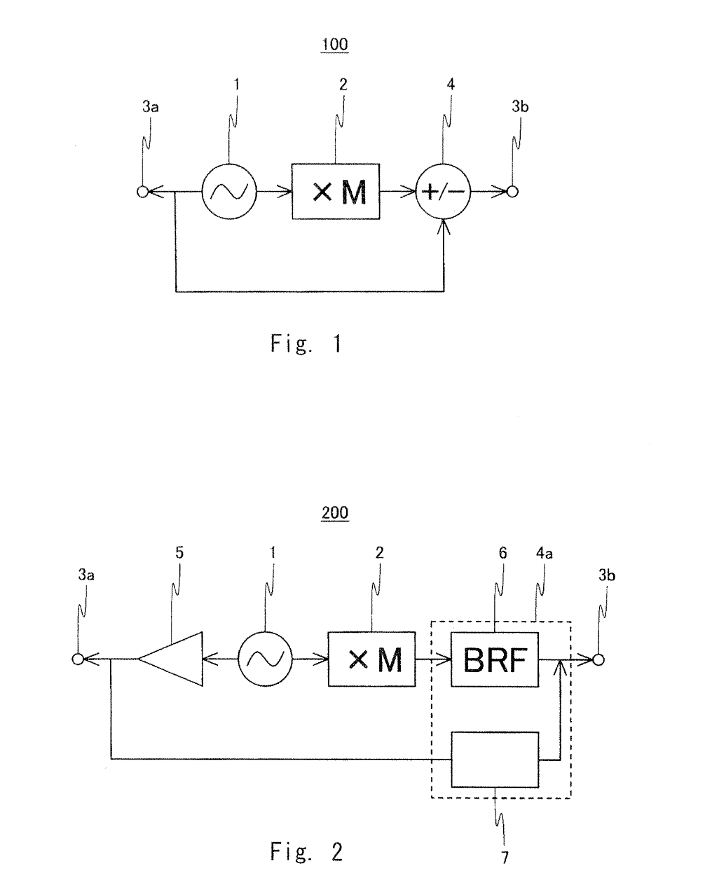

Hereinafter, exemplary embodiments of the present invention will be described with reference to the drawings. First, a frequency multiplier oscillation circuit 100 according to a first exemplary embodiment of the present invention will he described in detail. FIG. 1 is a configuration diagram of the frequency multiplier oscillation circuit 100 according to the first exemplary embodiment. The frequency multiplier oscillation circuit 100 includes, as shown in FIG. 1, an oscillation unit I including two output terminals. One output terminal of the oscillation unit 1 is connected to the input side of a multiplication unit 2 that outputs harmonics by non-linear behavior. The other output terminal of the oscillation unit 1 is connected to an output terminal 3a and a fundamental wave component removal unit 4. The output side of the multiplication unit 2 is connected to the fundamental wave component removal unit 4. The output side of the fundamental wave component removal unit 4 is connected to an output terminal 3b.

Subsequently, an operation of the frequency multiplier oscillation circuit 100 will be described. The frequency multiplier oscillation circuit 100 outputs a fundamental wave which is an oscillation frequency of the oscillation unit 1 from the output terminal 3a, and outputs a multiplied wave that is a desired harmonic generated by the multiplication unit 2 from the output terminal 3b.

The oscillation unit 1 outputs the fundamental wave to the output terminal 3a and the multiplication unit 2. The fundamental wave is output outside from the output terminal 3a. Further, the fundamental wave output from the oscillation unit 1 is divided, and a part of it (first fundamental wave) is input to the fundamental wave component removal unit 4. The multiplication unit 2 multiplies the fundamental wave output from the oscillation unit 1, to output a multiplied wave which is a desired harmonic to the fundamental wave component removal unit 4. At this time, not only that the multiplied wave is output, but also the fundamental wave (second fundamental wave) is leaked from the multiplication unit 2 to the fundamental wave component removal unit 4. Therefore, the multiplied wave output from the multiplication unit 2 includes a fundamental wave component (second fundamental wave).

The fundamental wave component removal unit 4 synthesizes the fundamental wave output from the oscillation unit 1 and the multiplied wave output from the multiplication unit 2. In this way, the fundamental wave component removal unit 4 cancels the fundamental wave component included in the multiplied wave, to output the multiplied wave to the output terminal 3b.

When the first fundamental wave and the second fundamental wave in the fundamental wave component removal unit 4 have opposite phases, the fundamental wave component removal unit 4 serves as an adder for the fundamental wave. Thus, the fundamental wave component removal unit 4 is able to add the fundamental wave output from the oscillation unit 1 and the fundamental wave component included in the multiplied wave by the same weighting, to cancel the fundamental wave component included in the multiplied wave. Accordingly, it is possible to suppress the spurious wave (fundamental wave) in the output terminal 3b.

When the first fundamental wave and the second fundamental wave in the fundamental wave component removal unit 4 have the same phase, the fundamental wave component removal unit 4 serves as a subtractor for the fundamental wave. Thus, the fundamental wave component removal unit 4 is able to perform subtraction of the fundamental wave output from the oscillation unit 1 and the fundamental wave component included in the multiplied wave by the same weighting, to cancel the fundamental wave component included in the multiplied wave. Accordingly, it is possible to suppress the spurious wave (fundamental wave) in the output terminal 3b.

The frequency multiplier oscillation circuit 100 is able to reduce non-linearity in the oscillator, as is different from the multiplier oscillator disclosed in Patent literature 1. Thus, the frequency multiplier oscillation circuit 100 is able to suppress spurious without increasing phase noise in the desired output multiplied wave. Further, as is different from the balanced multiplier disclosed in Non-patent literature 1, only the multiplication unit 2 is the non-linear element in the frequency multiplier oscillation circuit 100. Therefore, the fundamental wave can be suppressed with a simple configuration, which can make the frequency multiplier oscillation circuit compact. Accordingly. with this configuration, it is possible to achieve a frequency multiplier oscillation circuit which can he made compact and effectively suppress spurious, and a method of multiplying a fundamental wave.

### Second Exemplary Embodiment

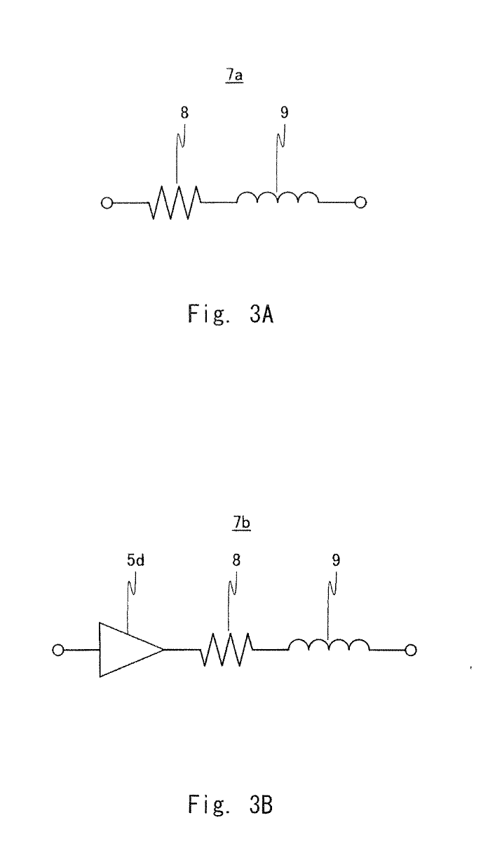

Next, a frequency multiplier oscillation circuit 200 according to a second exemplary embodiment of the present invention will be described in detail. FIG. 2 is a configuration diagram of the frequency multiplier oscillation circuit 200 according to the second exemplary embodiment. In the frequency multiplier oscillation circuit 200. a buffer amplifier 5 is added to the frequency multiplier oscillation circuit 100 shown in FIG. 1, and the fundamental wave component removal unit 4 is replaced with a fundamental wave component removal unit 4a. Note that the oscillation unit 1 in the frequency multiplier oscillation circuit 200 outputs a pair of differential signals as a fundamental wave. Since other configurations of the frequency multiplier oscillation circuit 200 are similar to those of the frequency multiplier oscillation circuit 100, description thereof will be omitted.

The fundamental wave component removal unit 4a includes a band-reject filter 6 and a coupling element 7. The band-reject filter 6 is connected between the multiplication unit 2 and the output terminal 3b, and suppresses the fundamental wave component included in the multiplied wave output from the multiplication unit 2. The coupling element 7 is connected between the buffer amplifier 5 and the output side of the band-reject filter 6, and adjusts the amplitude of the fundamental wave output from the oscillation unit I. The buffer amplifier 5 is connected between the oscillation unit I and the output terminal 3a.

Subsequently, an operation of the frequency multiplier oscillation circuit 200 will be described. The frequency multiplier oscillation circuit 200 outputs the fundamental wave which is the oscillation frequency of the oscillation unit I from the output terminal 3a, and outputs the multiplied wave which is a desired harmonic generated by the multiplication unit 2 from the output terminal 3b.

The oscillation unit 1 outputs one of differential signals that is a fundamental wave (hereinafter referred to as a first differential signal) to the buffer amplifier 5, and outputs the other one of the differential signals (hereinafter referred to as a second differential signal) to the input side of the multiplication unit 2. The buffer amplifier 5 amplifies the fundamental wave (first differential signal) to output the amplified wave to the output terminal 3a. The fundamental wave (first differential signal) that is amplified is output from the output terminal 3a. Further, a part of the fundamental wave (first differential signal) amplified by the buffer amplifier 5 is output to the output terminal 3b through the fundamental wave component removal unit 4a. It is possible to adjust the amplitude of the first differential signal (fundamental wave) output from the coupling element 7 to the output terminal 3b by adjusting the coupling degree of the coupling element 7.

The multiplication unit 2 multiplies the second differential signal output from the oscillation unit 1 to output the multiplied wave which is a desired harmonic to the band-reject filter 6. At this time, not only that the multiplied wave is output, but also the fundamental wave (second differential signal) is leaked from the multiplication unit 2 to the band-reject filter 6. The fundamental wave (second differential signal) leaked from the multiplication unit 2 is suppressed by the band-reject filter 6. However, a part of the fundamental wave (second differential signal) is leaked to the output terminal 3b. Therefore, the multiplied wave output from the band-reject filter 6 includes a fundamental wave component.

Consider now a case in which the phase of the output signal with respect to the phase of the input signal is inverted both in the buffer amplifier 5 and the multiplication unit 2. In this case, the fundamental wave (first differential wave) on the output side of the buffer amplifier 5 and the fundamental wave component (second differential signal) included in the multiplied wave output from the hand-reject filter 6 have opposite phases. Further, when the phase of the output signal with respect to the phase of the input signal is not inverted (non-inversion) both in the buffer amplifier 5 and the multiplication unit 2, the fundamental wave (first differential signal) on the output side of the buffer amplifier 5 and the fundamental wave component (second differential signal) included in the multiplied wave output from the band-reject filter 6 have opposite phases each other in the same way.

As described above, each of the buffer amplifier 5 and the multiplication unit 2 in which the phase of the output signal with respect to the phase of the input signal is inverted may be formed of, for example, a source-grounded electrical field effect transistor (Field Effect Transistor, hereinafter referred to as an FET) or an emitter-grounded bipolar transistor (Bipolar Transistor, hereinafter referred to as a BT). Further, each of the buffer amplifier 5 and the multiplication unit 2 in which the phase of the output signal with respect to the phase of the input signal is not inverted may be formed of a drain-grounded FET or a collector-grounded BT. By setting the gate bias in the FET or the base bias in the BT to a value which makes non-linearity high (typically, near threshold voltage), it can be used for the multiplication unit 2.

Accordingly, the frequency multiplier oscillation circuit 200 is able to cancel the fundamental wave component (second differential signal) included in the multiplied wave output from the band-reject filter 6 by the fundamental wave (first differential signal) output from the buffer amplifier 5 in the fundamental wave component removal unit 4a. Accordingly, in this configuration, the leakage level of the fundamental wave that appears in the output terminal 3b can be reduced.

Further, in order to sufficiently reduce the leakage level, it is required that the fundamental wave (first differential signal) output from the buffer amplifier 5 and the fundamental wave component (second differential signal) included in the multiplied wave output from the hand-reject filter 6 have the same amplitude. As described above, in the frequency multiplier oscillation circuit 200, the amplitude of the fundamental wave (first differential signal) output from the buffer amplifier 5 may he adjusted by adjusting the coupling degree of the coupling element 7, Accordingly, the amplitude of the fundamental wave (first differential signal) output from the buffer amplifier 5 can be made equal to the amplitude of the fundamental wave component (second differential signal) included in the multiplied wave output from the band-reject filter 6. Accordingly, in this configuration, the leakage level of the fundamental wave that appears in the output terminal 3b can be minimized.

Further, while there are frequency dependencies in the adjustment of the amplitude of the fundamental wave by the coupling element 7, there are no frequency dependencies for the phase of the fundamental wave. Therefore, it is possible to keep the phase of the fundamental wave (first differential signal) output from the buffer amplifier 5 and the phase of the fundamental wave component (second differential signal) included in the multiplied wave output from the band-reject filter 6 opposite with each other regardless of the frequency of the fundamental wave. Accordingly, in this configuration, the leakage level of the fundamental wave that appears in the output terminal 3b can be reduced over a wide band.

Further, in a typical communication system, the oscillator often forms phase-locked loop. In this case, in order to compare the phases with a low-frequency signal source which is the standard, the frequency of a high-frequency signal from the oscillator needs to be divided. In such a case, according to this configuration, there is an advantage that a frequency divider adapted for high-frequency operation is not necessary by outputting two frequency bands of the fundamental wave and the multiplied wave.

In the frequency multiplier oscillation circuit 200, it is desirable that the coupling element 7 is able to obtain a desired coupling degree with respect to the fundamental wave and the influence on the multiplied wave is small. Accordingly, the impedance of the coupling element 7 when the coupling element 7 is seen from the output terminal 3b is preferably as high as possible in the frequency of the multiplied wave. A resistance element which achieves high impedance with no frequency dependencies, an inductor element which achieves high impedance in a high-frequency hand may he used as such a coupling element 7.

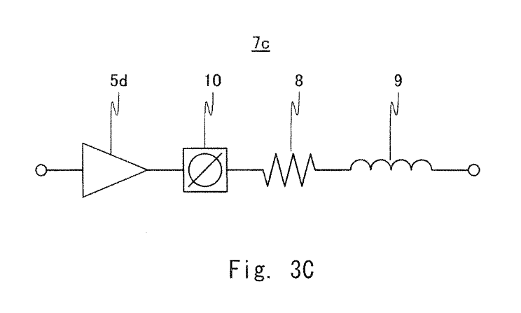

FIGS. 3A to 3C are configuration diagrams showing configurations of coupling elements 7a to 7c that are configuration examples of the coupling element 7. The coupling element 7a may have such a configuration as shown in FIG. 3A in which a resistance element 8 and an inductor element 9 are connected in series. Accordingly, the degree of freedom to set the frequency characteristics of the impedance increases. which makes it possible to obtain a desired coupling degree more easily.

Further. in the coupling element 7b, as shown in FIG. 3B, an amplifier 5d is added to the coupling element 7a shown in FIG. 3A, to secure the isolation from the output terminal 3b to the output terminal 3a. In this example. the input side of the amplifier 5d is connected to the output terminal 3a. Accordingly, the leakage of the multiplied wave to the output terminal 3a can be suppressed. However, in the output terminal 3b, in order to make the phases of the fundamental waves output from the coupling element 7a and the band-reject filter 6 opposite with each other, the phase of the output signal with respect to the phase of the input signal of the amplifier 5d needs to be non-inverted. In this case as well, it is desirable that the impedance when the coupling element 7 is seen from the output terminal 3b becomes high. Specifically, an end of the part in which the resistance element 8 and the inductor element 9 are connected in series is connected to the output terminal 3b.

While described above is the case in which the phase of the output signal with respect to the phase of the input signal in the multiplication unit 2, the buffer amplifier 5, and the amplifier 5d is ideally inverted or non-inverted, there are generated some phase shift in reality. Therefore, as shown in the coupling element 7c shown in FIG. 3C, a phase shift element 10 may be added to compensate the phase shift. Further, it is possible to compensate the shift the like from the design due to manufacturing variations by using each element in the coupling element 7 (the resistance element 8, the inductor element 9. the amplifier 5d, and the phase shift element 10) that can be controlled.

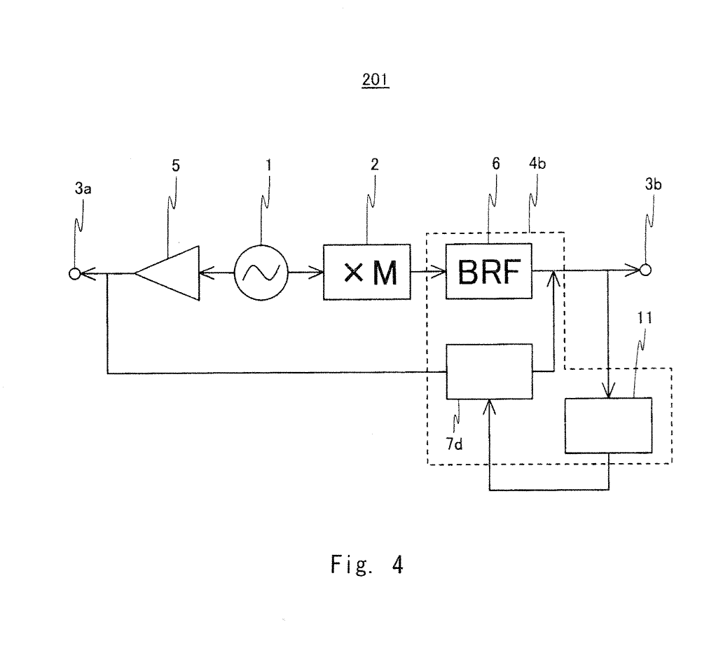

FIG. 4 is a configuration diagram showing a configuration of a frequency multiplier oscillation circuit 201, which is an example obtained by modifying the configuration of the frequency multiplier oscillation circuit 200. As shown in FIG. 4, compared with the frequency multiplier oscillation circuit 200, the fundamental wave component removal unit 4a is replaced with a fundamental wave component removal unit 4b in the frequency multiplier oscillation circuit 201. The fundamental wave component removal unit 4b includes a variable coupling element 7d and a leakage wave detection unit 11. The leakage wave detection unit 11 detects the leakage level of the fundamental wave in the output terminal 3b. Now, the leakage level of the fundamental wave means the amplitude of the fundamental wave component output from the fundamental wave component removal unit 4b.

The output side of the leakage wave detection unit 11 is connected to the variable coupling element 7d whose coupling degree can be varied. In this way, it is possible to dramatically control the coupling degree of the variable coupling element 7d while monitoring the leakage level of the fundamental wave in the output terminal 3b. Accordingly, it is possible to suppress the leakage wave of the fundamental wave more efficiently compared to the frequency multiplier oscillation circuit 200.

### Third Exemplary Embodiment

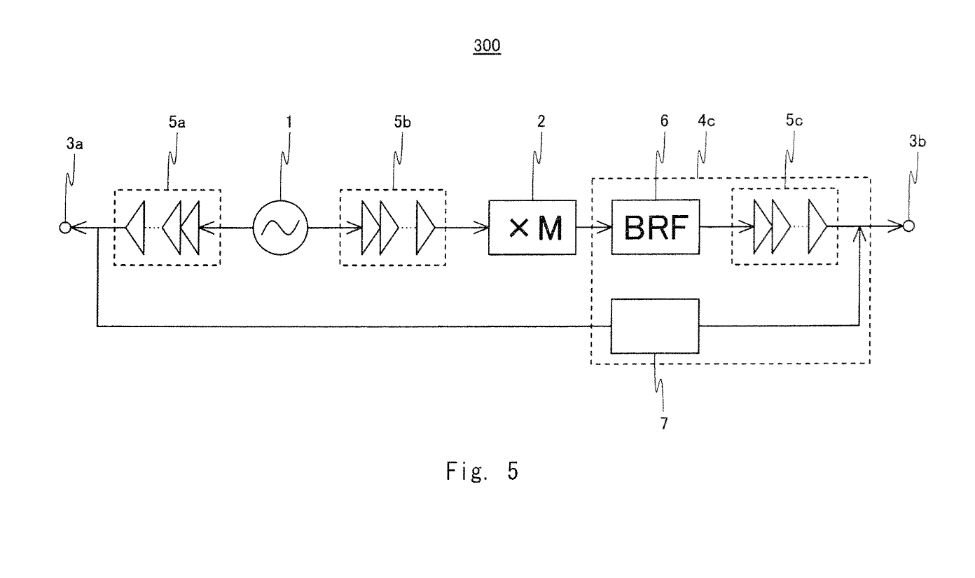

Next, a frequency multiplier oscillation circuit 300 according to a third exemplary embodiment of the present invention will be described in detail. FIG. 5 is a configuration diagram of the frequency multiplier oscillation circuit 300 according to the third exemplary embodiment. In the frequency multiplier oscillation circuit 300, as shown in FIG. 5, the buffer amplifier 5 of the frequency multiplier oscillation circuit 200 shown in FIG. 2 is replaced with a buffer amplifier 5a including a plurality of amplifying stages, and the fundamental wave component removal unit 4a is replaced with a fundamental wave component removal unit 4c. Further, a buffer amplifier 5b including a plurality of amplifying stages is added to the frequency multiplier oscillation circuit 300. The buffer amplifier 5b is connected between the oscillation unit I and the multiplication unit 2.

Compared to the fundamental wave component removal unit 4a, the fundamental wave component removal unit 4c includes an amplifier 5c added to the output side of the band-reject filter 6. Other configurations are similar to those in the frequency multiplier oscillation circuit 200, and thus description thereof will be omitted.

Subsequently, an operation of the frequency multiplier oscillation circuit 300 will be described. The frequency multiplier oscillation circuit 300 outputs a fundamental wave which is an oscillation frequency of the oscillation unit 1 from the output terminal 3a, and outputs a multiplied wave which is a desired harmonic generated by the multiplication unit 2 from the output terminal 3b.

The oscillation unit 1 outputs one of differential signals which is a fundamental wave (first differential signal) to the buffer amplifier 5a, and the other one of the differential signals (second differential signal) to the input side of the buffer amplifier 5b. The buffer amplifier 5a amplifies the fundamental wave (first differential signal) to output the amplified wave to the output terminal 3a. The fundamental wave (first differential signal) that is amplified is output from the output terminal 3a. Further, a part of the fundamental wave (first differential signal) amplified by the buffer amplifier 5a is output to the fundamental wave component removal unit 4c.

The buffer amplifier 5b amplifies the fundamental wave (second differential signal) to output the amplified wave to the multiplication unit 2. The multiplication unit 2 multiplies the fundamental wave (second differential signal) to output the multiplied wave which is a desired harmonic to the band-reject filter 6. At this time, not only that the multiplied wave is output, but also the fundamental wave (second differential signal) is leaked from the multiplication unit 2 to the band-reject filter 6. The fundamental wave (second differential signal) leaked from the multiplication unit 2 is suppressed by the band-reject filter 6. However, a part of the fundamental wave (second differential signal) leaks to the amplifier 5c. The amplifier 5c amplifies the multiplied wave including the fundamental wave component output from the band-reject filter 6 to output the amplified wave. This means that the multiplied wave included from the amplifier 5c also includes a fundamental wave component.

The number of steps that the phase of the fundamental wave (first differential signal) is inverted in the buffer amplifier 5a including a plurality of amplifying steps is denoted by n (n is an integer of 0 or larger). Further, the number of steps that the phase of the fundamental wave (second differential signal) is inverted in the buffer amplifier 5b the multiplication unit 2, and the amplifier 5c is denoted by m (m is an integer of 0 or larger). When |n−m| is an even number, the fundamental wave on the output side of the buffer amplifier 5a and the fundamental wave component of the multiplied wave output from the amplifier 5c have opposite phases with each other.

In the similar way as the frequency multiplier oscillation circuit 200, the frequency multiplier oscillation circuit 300 is able to cancel the fundamental wave component (second differential signal) included in the multiplied wave output from the band-reject filter 6 by the fundamental wave (first differential signal) output from the buffer amplifier 5 in the fundamental wave component removal unit 4c. Accordingly, in this configuration, the leakage level of the fundamental wave that appears in the output terminal 3b can be reduced.

Further, when |n−m| is an odd number, the fundamental wave on the output side of the buffer amplifier 5a and the fundamental wave component of the multiplied wave output from the amplifier 5c have the same phase. In such a case, it is required that the phase of the output signal with respect to the phase of the input signal of the coupling element 7 is inverted. In this case, for example, the coupling element 7 may include the amplifier 5d in which the phase of the output signal with respect to the phase of the input signal is inverted in the coupling element 7b shown in FIG. 3B. Further, the phase of the fundamental wave output from the buffer amplifier 5a may be made opposite to the phase of the fundamental wave component of the multiplied wave output from the amplifier 5c in the fundamental wave component removal unit 4c by the phase shift element 10 of the coupling element 7c. Accordingly, it is possible to reduce the leakage level of the fundamental wave that appears in the output terminal 3b.

Subsequently, a case in which the oscillation unit 1 outputs a fundamental wave which is not differential signals will be described. In this case, the oscillation unit 1 outputs a first fundamental wave to the buffer amplifier 5a and outputs a second fundamental wave to the buffer amplifier 5b. Therefore, when |n−m| is an odd number, the fundamental wave on the output side of the buffer amplifier 5a and the fundamental wave component included in the multiplied wave output from the amplifier 5c have opposite phases with each other. Meanwhile, when |n−m| is an even number, the fundamental wave on the output side of the buffer amplifier 5a and the fundamental wave component included in the multiplied wave output from the amplifier 5c have the same phase. In this case, the coupling element 7c is appropriately arranged or the first fundamental wave and the second fundamental wave are synthesized (subtracted) in the fundamental wave component removal unit so that they have opposite phases, thereby capable of reducing the leakage level of the fundamental wave that appears in the output terminal 3b.

### Fourth Exemplary Embodiment

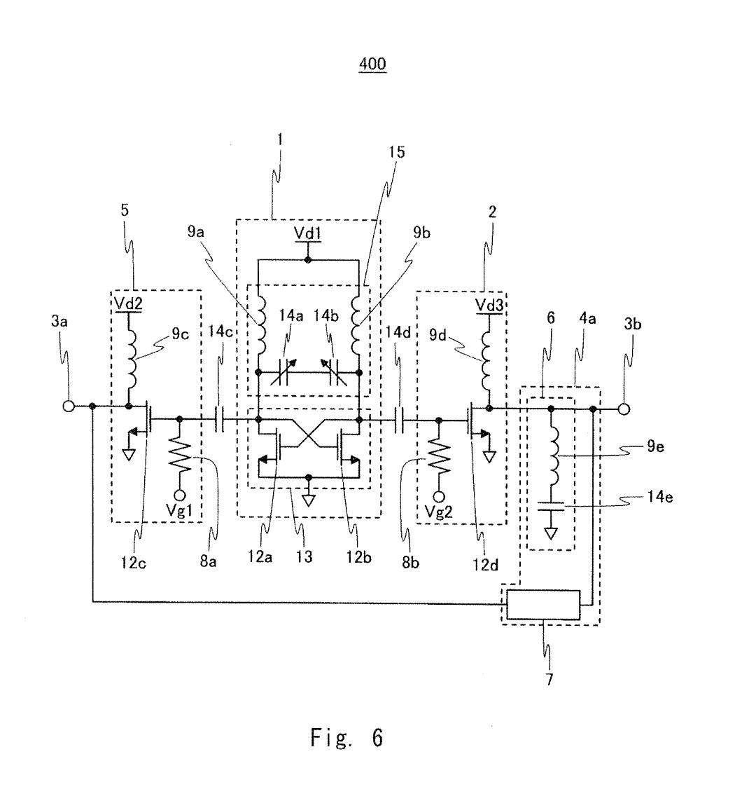

Next, a frequency multiplier oscillation circuit 400 according to a fourth exemplary embodiment of the present invention will be described in detail. FIG. 6 is a configuration diagram of the frequency multiplier oscillation circuit 400 according to the fourth exemplary embodiment. As shown in FIG. 6, the frequency multiplier oscillation circuit 400 shows a detailed configuration of the frequency multiplier oscillation circuit 200 shown in FIG. 2.

The oscillation unit 1 includes two differential output terminals. One differential output terminal is connected to the buffer amplifier 5 through a DC cut capacitor element 14c that interrupts a power supply Vd1 of the oscillation unit 1. The other differential output terminal is connected to the multiplication unit 2 through a DC cut capacitor element 14d that interrupts the power supply Vd1 of the oscillation unit 1.

The oscillation unit 1 includes a negative resistance unit 13 and an LC resonator 15. The negative resistance unit 13 includes FET 12a and FET 12b that are cross-linked. The drain of the FET 12a is connected to the gate of the FET 12b, the DC cut capacitor element 14c, and the LC resonator 15. The drain of the FET 12b is connected to the gate of the FET 12a, the DC cut capacitor element 14d, and the LC resonator 15. The sources of the FET 12a and the FET 12b are connected to the ground, The LC resonator 15 includes a capacitor element 14a, a capacitor element 14b, an inductor element 9a, and an inductor element 9b. The capacitor element 14a and the capacitor element 14b are variable capacitance elements, and are able to change the oscillation frequency by controlling capacitance values of the capacitor element 14a and the capacitor element 14b. The inductor element 9a has one end connected to the power supply Vd1, and the other end connected to the drain of the FET 12a. The inductor element 9b has one end connected to the power supply Vd1, and the other end connected to the drain of the FET 12b. Further, ends of the inductor element 9a and the inductor element 9b on the side of the negative resistance unit 13 are connected each other through the capacitor element 14a and the capacitor element 14b connected in series.

The buffer amplifier 5 includes an FET 12c, a gate bias applying resistor 8a, and a power supply inductor element 9c. The gate of the FET 12c receives differential signals through the DC cut capacitor element 14c, and is applied with a gate bias Vg1 through the gate bias applying resistor 8a. The drain of the FET 12c is connected to a power supply Vd2 through the power supply inductor element 9c, and the source of the FET 12c is connected to the ground.

The multiplication unit 2 includes a FET 12d, a gate bias applying resistor 8b, and a power supply inductor element 9d. The gate of the FET 12d receives differential signals through the DC cut capacitor element 14d, and is applied with a gate bias Vg2 through the gate bias applying resistor 8b. The drain of the FET 12d is connected to a power supply Vd3 through the power supply inductor element 9d, and the source of the FET 12d is connected to the ground. Note that the gate bias Vg2 of the multiplication unit 2 is set to have high non-linearity in order to generate large harmonics n general. near threshold voltage).

The fundamental wave component removal unit 4a includes a band-reject filter 6 and a coupling clement. The band-reject filter 6 is a series resonator that includes a capacitor element 14e and an inductor element 9c and resonates at the fundamental wave frequency. Since the impedance at the resonance frequency becomes low at the connection point of the band-reject filter 6, the fundamental wave can he suppressed.

Accordingly, this configuration makes it possible to reduce the leakage level of the fundamental wave that appears in the output terminal 3b in the similar way as the frequency multiplier oscillation circuit 200.

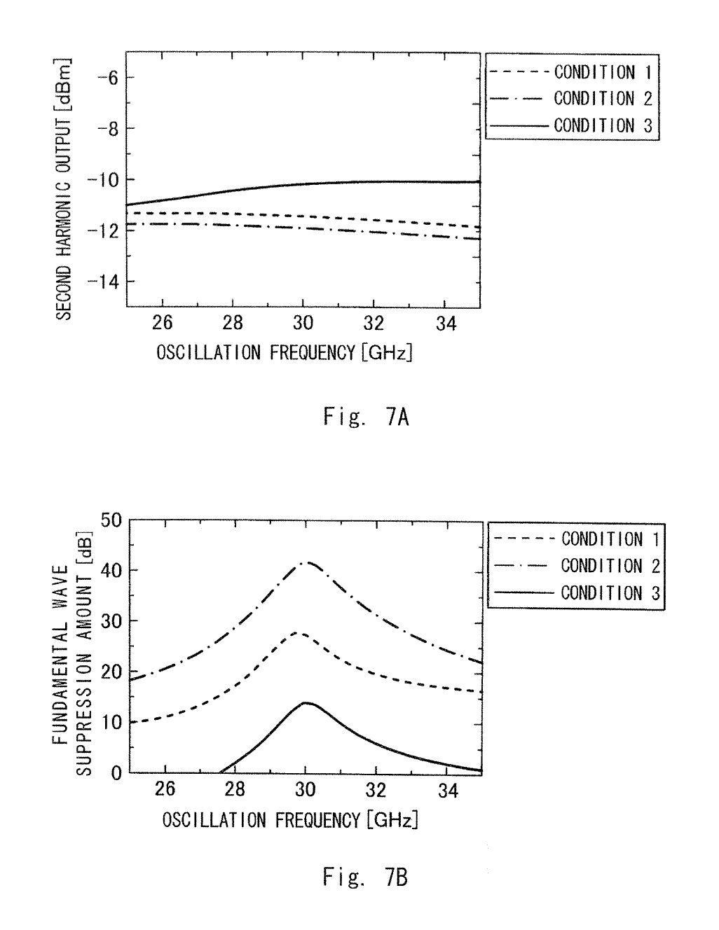

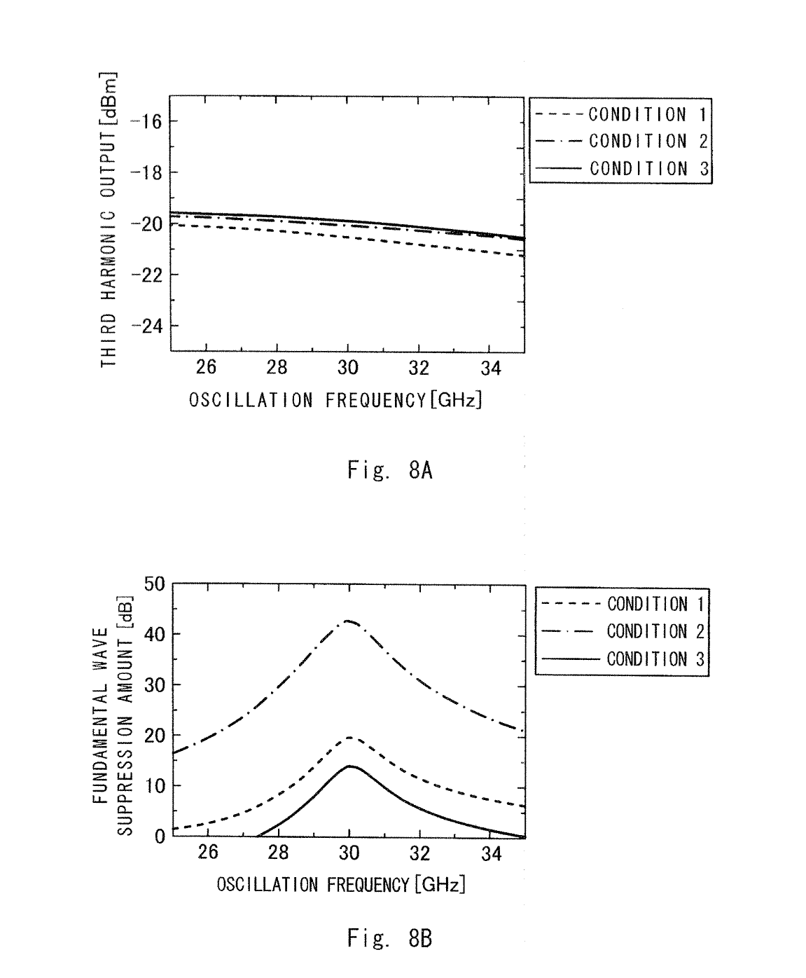

Subsequently, effects of improving the suppression level of the fundamental wave and output of multiplied waves in the frequency multiplier oscillation circuit 400 will be described taking double multiplication and triple multiplication as examples. FIG. 7A is a graph showing frequency characteristics of output power of the multiplied waves when the frequency multiplier oscillation circuit 400 outputs second harmonics. FIG. 7B is a graph showing frequency characteristics of the fundamental wave suppression level when the frequency multiplier oscillation circuit 400 outputs the second harmonics. FIG. 8A is a graph showing frequency characteristics of output power of the multiplied waves when the frequency multiplier oscillation circuit 400 outputs third harmonics. FIG. 8B is a graph showing frequency characteristics of the fundamental wave suppression level when the frequency multiplier oscillation circuit 400 outputs the third harmonics. In FIGS. 7A, 7B, 8A, and 8B a case in which the coupling element 7 includes a resistance element (R coupling, condition 1), and a case in which the coupling element 7 includes a series connection element of a resistance element and an inductor element (LR coupling, condition 2) are shown. Further, a case in which there is no coupling element 7 (condition 3) is shown as a comparative example. In FIGS. 7A, 7B, 8A, and 8B, in conditions 1-3, the oscillation frequencies are changed by changing the capacitor values of the capacitor element 14a and the capacitor element 14b.

As shown in FIGS. 7B and 8B, it is shown that, in the frequency multiplier oscillation circuit 400 (condition 1 or condition 2), the fundamental wave suppression level is improved compared to the case in which there is no coupling element (condition 3). Further, since the frequency dependencies of the inductor element can he used in the coupling element of the LR coupling (condition 2), it is possible to further improve the suppression level of the fundamental wave compared to the coupling element of the R coupling (condition 1) with no frequency dependencies.

Further, compared to the case of double multiplication, the difference in the frequency from that of the fundamental wave which is to be suppressed is larger in the case of the triple multiplication. Accordingly, the frequency dependencies of the inductor element can be used more widely, thereby capable of reducing the influence on the multiplied waves by the coupling element 7 as shown in FIGS. 7A and 8A.

### Other Exemplary Embodiments

Note that the present invention is not limited to the description in the exemplary embodiments stated above, but may be changed as appropriate without departing from the spirit of the present invention. For example, the configurations of the coupling elements 7a-7c shown in FIGS. 3A to 3C and the variable coupling element 7d shown in FIG. 4 are merely examples. Thus, other passive elements and active elements may be appropriately combined to form the coupling element 7 as long as a desired coupling degree can be obtained.

Further, in the frequency multiplier oscillation circuits 100 and 300, the coupling element 7 can be replaced with any of the coupling elements 7a to 7c, in the similar way as the frequency multiplier oscillation circuit 200. Further, it is possible to dramatically control the coupling degree of the coupling element by adding the leakage wave detection unit 11 shown in FIG. 4.

While the present invention has been described with reference to the exemplary embodiments stated above, the present invention is not limited to the above description. Various changes that can be understood by a person skilled in the art may be made to the configuration and the detail of the present invention within the scope of the present invention.

This application claims the benefit of priority, and incorporates herein by reference in its entirety, the following Japanese Patent Application No. 2010-37203 filed on Feb. 23, 2010.

### INDUSTRIAL APPLICABILITY

The present invention is applicable to a signal source, an oscillator, a multiplier, and the like that generate high-frequency signals.

### REFERENCE SIGNS LIST

1 OSCILLATION UNIT

2 MULTIPLICATION UNIT

3a, 3b OUTPUT TERMINAL

4, 4a-4c FUNDAMENTAL WAVE COMPONENT REMOVAL UNIT

5 BUFFER AMPLIFIER

5a, 5b BUFFER AMPLIFIER

5c, 5d AMPLIFIER

6 BAND-REJECT FILTER

7, 7a, 7c, 7b COUPLING ELEMENT

7d VARIABLE COUPLING ELEMENT

8 RESISTANCE ELEMENT

8a, 8b GATE BIAS APPLYING RESISTOR

9, 9a, 9b INDUCTOR ELEMENT

9c, 9d POWER SUPPLY INDUCTOR ELEMENT

9e INDUCTOR ELEMENT

10 PHASE SHIFT ELEMENT

11 LEAKAGE WAVE DETECTION UNIT

12a, 12b, 12c, 12d FET

13 NEGATIVE RESISTANCE UNIT

14a, 14b CAPACITOR ELEMENT

14c, 14d DC CUT CAPACITOR ELEMENT

14e CAPACITOR ELEMENT

15 RESONATOR

100, 200, 201, 300, 400 FREQUENCY MULTIPLIER OSCILLATION CIRCUIT

Vd1-3 POWER SUPPLY

Vg1, Vg2 GATE BIAS

1. A frequency multiplier oscillation circuit comprising:
a oscillation unit that outputs a fundamental wave;
a multiplication unit that multiplies the fundamental wave output from the oscillation unit to output the multiplied wave; and
a fundamental wave component removal unit that cancels a fundamental wave component included in the multiplied wave based on the fundamental wave output from the oscillation unit to output the multiplied wave.

2. The frequency multiplier oscillation circuit according to claim 1, wherein
the fundamental wave component removal unit adds the fundamental wave output from the oscillation unit and the fundamental wave component included in the multiplied wave when the fundamental wave output from the oscillation unit and the fundamental wave component included in the multiplied wave have opposite phases with each other, and
the fundamental wave component removal unit performs subtraction of the fundamental wave output from the oscillation unit and the fundamental wave component included in the multiplied wave when the fundamental wave output from the oscillation unit and the fundamental wave component included in the multiplied wave have a same phase.

3. The frequency multiplier oscillation circuit according to claim 1, wherein the fundamental wave component removal unit at least comprises a coupling element for changing an amplitude of the fundamental wave output from the oscillation unit.

4. The frequency multiplier oscillation circuit according to claim 3, wherein
the fundamental wave component removal unit further comprises a detector that outputs a control signal according to an amplitude of the fundamental wave component remaining in the multiplied wave output from the fundamental wave component removal unit, and
the coupling element changes the amplitude of the fundamental wave output from the oscillation unit according to the control signal.

5. The frequency multiplier oscillation circuit according to claim 3, wherein the coupling element comprises a phase shift element for adjusting the phase of the fundamental wave output from the oscillation unit.

6. The frequency multiplier oscillation circuit according to claim 5, wherein the phase shift element adjusts the phase of the fundamental wave output from the oscillation unit so that the fundamental wave output from the oscillation unit and the fundamental wave component included in the multiplied wave in the fundamental wave component removal unit have a same phase or opposite phases with each other.

7. The frequency multiplier oscillation circuit according claim 1, wherein the amplitude of the fundamental wave output from the oscillation unit and the amplitude of the fundamental wave component included in the multiplied wave in the fundamental wave component removal means unit are equal to each other.

8. The frequency multiplier oscillation circuit according to claim 1, wherein
the oscillation unit outputs a first fundamental wave to the fundamental wave component removal unit,
the oscillation unit outputs a second fundamental wave to the multiplication unit, the second fundamental wave having a same frequency as a frequency of the first fundamental wave and having a phase inverted with respect to a phase of the first fundamental wave,
the phase of the first fundamental wave is inverted n (n is an integer of 0 or larger) times before the first fundamental wave arrives at the fundamental wave component removal unit,
the phase of the second fundamental wave component included in the multiplied wave is inverted m (m is an integer of 0 or larger) times before the second fundamental wave component arrives at the fundamental wave component removal unit,
the fundamental wave component removal unit performs subtraction of the first fundamental wave and the second fundamental wave component included in the multiplied wave when |n−m| is an odd number, and
the fundamental wave component removal unit adds the first fundamental wave and the second fundamental wave component included in the multiplied wave when |n−m| is an even number.

9. The frequency multiplier oscillation circuit according to claim 1, wherein
the oscillation unit outputs a first fundamental wave to the fundamental wave component removal unit,
the oscillation unit outputs a second fundamental wave to the multiplication unit, the second fundamental wave having a same frequency as a frequency of the first fundamental wave and having a same phase as a phase of the first fundamental wave,
the phase of the first fundamental wave is inverted n (n is an integer of 0 or larger) times before the first fundamental wave arrives at the fundamental wave component removal unit,
the phase of the second fundamental wave component included in the multiplied wave is inverted m (m is an integer of 0 or larger) times before the second fundamental wave component arrives at the fundamental wave component removal unit,
the fundamental wave component removal unit adds the first fundamental wave and the second fundamental wave component included in the multiplied wave when |n−m| is an odd number, and
the fundamental wave component removal unit performs subtraction of the first fundamental wave and the second fundamental wave component included in the multiplied wave when |n−m| is an even number.

10. A method of multiplying a fundamental wave comprising:
outputting a fundamental wave from oscillation means;
multiplying the fundamental wave to output the multiplied wave; and
cancelling a fundamental wave component included in the multiplied wave based on the fundamental wave output from the oscillation means to output the multiplied wave.

11. A frequency multiplier oscillation circuit comprising:
oscillation means for outputting a fundamental wave;
multiplication means for multiplying the fundamental wave output from the oscillation means to output the multiplied wave; and
fundamental wave component removal means for cancelling a fundamental wave component included in the multiplied wave based on the fundamental wave output from the oscillation means to output the multiplied wave.

12. The frequency multiplier oscillation circuit according to claim 11, wherein the fundamental wave component removal means adds the fundamental wave output from the oscillation means and the fundamental wave component included in the multiplied wave when the fundamental wave output from the oscillation means and the fundamental wave component included in the multiplied wave have opposite phases with each other, and
the fundamental wave component removal means performs subtraction of the fundamental wave output from the oscillation means and the fundamental wave component included in the multiplied wave when the fundamental wave output from the oscillation means and the fundamental wave component included in the multiplied wave have a same phase.

13. The frequency multiplier oscillation circuit according to claim 11, wherein the fundamental wave component removal means at least comprises a coupling element for changing an amplitude of the fundamental wave output from the oscillation means.

14. The frequency multiplier oscillation circuit according to claim 13, wherein
the fundamental wave component removal means further comprises detection means for outputting a control signal according to an amplitude of the fundamental wave component remaining in the multiplied wave output from the fundamental wave component removal means, and
the coupling element changes the amplitude of the fundamental wave output from the oscillation means according to the control signal.

15. The frequency multiplier oscillation circuit according to claim 13, wherein the coupling element comprises a phase shift element for adjusting the phase of the fundamental wave output from the oscillation means.

16. The frequency multiplier oscillation circuit according to claim 15, wherein the phase shift element adjusts the phase of the fundamental wave output from the oscillation means so that the fundamental wave output from the oscillation means and the fundamental wave component included in the multiplied wave in the fundamental wave component removal means have a same phase or opposite phases with each other.

17. The frequency multiplier oscillation circuit according to claim 11, wherein the amplitude of the fundamental wave output from the oscillation means and the amplitude of the fundamental wave component included in the multiplied wave in the fundamental wave component removal means are equal to each other.

18. The frequency multiplier oscillation circuit according to claim 11, wherein
the oscillation means outputs a first fundamental wave to the fundamental wave component removal means,
the oscillation means outputs a second fundamental wave to the multiplication means, the second fundamental wave having a same frequency as a frequency of the first fundamental wave and having a phase inverted with respect to a phase of the first fundamental wave,
the phase of the first fundamental wave is inverted n (n is an integer of 0 or larger) times before the first fundamental wave arrives at the fundamental wave component removal means,
the phase of the second fundamental wave component included in the multiplied wave is inverted m (m is an integer of 0 or larger) times before the second fundamental wave component arrives at the fundamental wave component removal means,
the fundamental wave component removal means performs subtraction of the first fundamental wave and the second fundamental wave component included in the multiplied wave when |n−m| is an odd number, and
the fundamental wave component removal means adds the first fundamental wave and the second fundamental wave component included in the multiplied wave when |n−m| is an even number.

19. The frequency multiplier oscillation circuit according to claim 11, wherein
the oscillation means outputs a first fundamental wave to the fundamental wave component removal means,
the oscillation means outputs a second fundamental wave to the multiplication means, the second fundamental wave having a same frequency as a frequency of the first fundamental wave and having a same phase as a phase of the first fundamental wave,
the phase of the first fundamental wave is inverted n (n is an integer of 0 or larger) times before the first fundamental wave arrives at the fundamental wave component removal means,
the phase of the second fundamental wave component included in the multiplied wave is inverted m (m is an integer of 0 or larger) times before the second fundamental wave component arrives at the fundamental wave component removal means,
the fundamental wave component removal means adds the first fundamental wave and the second fundamental wave component included in the multiplied wave when |n−m| is an odd number, and
the fundamental wave component removal means performs subtraction of the first fundamental wave and the second fundamental wave component included in the multiplied wave when |n−m| is an even number.
